(19) United States
(12) Patent Application Publication
(10) Pub. No.: US 2005/0101120 A1
(43) Pub. Date: May 12, 2005

(54) Method of forming local interconnect barrier layers

(76) Inventors: Fred Hause, Austin, TX (US); Gert Burbach, Dresden (DE); Volker Kahlert, Dresden (DE)

Correspondence Address: WILLIAMS, MORGAN & AMERSON, P.C., 10333 RICHMOND, SUITE 1100, HOUSTON, TX, 77042, US

(21) Appl. No.: 10/400,212

(22) Filed: Mar. 27, 2003

(30) Foreign Application Priority Data
Aug. 30, 2002 (DE) 102 40 116.0

(51) Int. Cl. H01L 21/44; H01L 21/4763

(52) U.S. Cl. 438/627; 438/643; 438/653; 438/685

(57) ABSTRACT

In a barrier formation process, an adhesion layer of refractory metal is deposited on sidewalls and bottom portions of a trench, and, subsequently, a nitride layer of the refractory metal is formed on the adhesion layer. After forming the nitride layer, the substrate is subjected to a heat treatment in a nitrogen-containing atmosphere to further convert residual refractory metal into nitride, thereby improving the barrier properties of the nitride layer in a subsequent process for filling in a contact metal, such as tungsten.

### BACKGROUND OF THE INVENTION

1. Field of the Invention

The present invention relates to the field of fabrication of integrated circuits, and, more particularly, to forming local interconnect barrier layers (LIB layers) in interconnection metal structures of integrated circuits.

2. Description of the Related Art

In recent years, refractory metals (i.e., tungsten, titanium, molybdenum and tantalum) have been largely adopted for various applications in the interconnect systems of silicon integrated circuits. Generally, a local interconnect system is a wiring layer containing conductive lines and vias to provide for the electrical connection between adjacent circuit elements according to the required circuit function. Tungsten is frequently used in forming local interconnects, among others, for two important applications. One application is the use as a plug, i.e., a conductive element completely filling a via between aluminum lines or between a metal line and a contact portion of a circuit element. Tungsten is often chosen as a plug material in technologies in which the minimum feature size is less than 1 micron because tungsten deposited by a chemical vapor deposition (CVD) process provides more superior via filling capabilities than aluminum. The second, somewhat lesser role of CVD tungsten is to serve as a connecting line for essentially the same reasons as listed above.

With reference to FIGS. 1a-1c, some examples of corresponding applications will be discussed in which tungsten is used for interconnection structures of integrated circuits. FIG. 1a shows a schematic cross-sectional view of a typical interconnect structure 100 including a trench 3 filled with tungsten 3′ and formed in a dielectric layer 2, for instance a silicon oxide layer, previously grown on a wafer 1, for instance a silicon wafer. In this way, conductive planar lines comprised of tungsten that electrically connect separated devices and/or circuits on the wafer 1 are formed.

In FIG. 1b, a further example of an application of tungsten is given in which tungsten is used as a plug for filling conducting vias. In the particular example depicted in FIG. 1b, tungsten 4′ has been used for filling, for instance according to a well-known chemical vapor deposition process, a contact hole 4 previously formed in a dielectric layer 2. In this way, a vertical electrical contact is formed, for instance for contacting a metal layer 5 embedded in the dielectric layer 2. Alternatively, as depicted in FIG. 1c, contact holes or vias 6 can be filled with tungsten for contacting a predefined region 7 of the wafer 1, for instance a heavily doped region.

Of course, tungsten may be used for a combination of two or more of the applications depicted above. For example, as depicted in FIG. 1c, planar conducting lines 3′ and vertical contacting plugs 4′ and 6′ may be formed for contacting separated devices and/or circuits as well as metal layers 5 and predefined regions 7.

Typically, the use of tungsten for forming plugs and/or local interconnects requires supporting films to be fabricated beneath the tungsten. This is essentially due to two reasons: first, tungsten exhibits high resistivity, about twice as high as that of aluminum-alloy films; second, tungsten films adhere purely to oxide and nitride layers. Accordingly, before filling the trenches and/or vias with tungsten, contact and adhesion layers are deposited, either by CVD or sputter deposition. Currently, the most widely used materials for the contact and adhesion layers are titanium and titanium nitride, respectively. Alternatively, other refractory metals and refractory metal nitrides, such as, for example, tantalum and tantalum nitride, can be used for this purpose.

Frequently, a thin layer of titanium (30-50 nm thick) is used under a titanium nitride adhesion layer because titanium provides lower contact resistance to the silicon substrate than titanium nitride. The adhesion layer is needed because of the extremely poor adhesion of tungsten deposited by CVD to such insulators as thermal oxide, plasma-enhanced oxide and plasma-enhanced silicon nitride. Tungsten, however, adheres well to titanium nitride, and titanium nitride, in turn, adheres well to these insulators. Thus, a method which allows forming layers exhibiting both good adhesion to the substrate and low contact resistivity is achieved.

A typical process flow for forming tungsten interconnection structures having contact/adhesion layers will be described in the following with reference to FIGS. 2a-2c. Although a description will be given of a process flow for forming planar interconnect lines, it has to be noted that the process flow may also be used for forming other interconnection structures, for example vertical plugs.

FIG. 2a shows a semiconductor structure 200 including a trench 3 formed in a dielectric layer 2 that is provided on a substrate 1. A contact layer 9 and an adhesion/barrier layer 10 are formed on a surface 8 of the dielectric layer 2. A process flow for forming the semiconductor structure 200 may be as follows.

In a first step, the desired conductive pattern is defined as the recess or trench 3 formed by conventional photolithographic and etching techniques in the surface 8 of the dielectric layer 2 that is comprised of, for example, a silicon oxide and/or nitride or an organic polymeric material. Next, the contact layer 9 comprising, e.g., titanium or tantalum and the overlying adhesion/barrier layer 10 comprised of, e.g., titanium nitride or tantalum nitride are subsequently deposited by well-known techniques such as physical vapor deposition (PVD), chemical vapor deposition (CVD) and plasma-enhanced chemical vapor deposition (PECVD).

FIG. 2b shows the semiconductor structure 200 with a tungsten layer 11 formed thereon. The tungsten layer 11 is deposited, for instance by a chemical vapor deposition, to fill the recess 3. In order to ensure complete filling of the recess 3, the tungsten layer 11 is deposited as a blanket or overburden layer of excess thickness so as to overfill the recess 3 and also cover the portions of the layers 9, 10 outside the trench 3.

FIG. 2c depicts the semiconductor structure 200 with a tungsten interconnect line 11′ after removal of the excess thickness of the tungsten layer 11 as well as the layers 9 and 10 outside the trench 3, for instance by a chemical mechanical polishing (CMP) process.

Besides serving as an adhesion layer, the layer 10 depicted in FIG. 2c also acts as a diffusion barrier. That is, it also substantially prevents products and by-products of the chemical reaction for filling the trench 3 with tungsten from reacting with the contact layer 9. In those applications where no contact layers are needed, the adhesion layer 10 also acts as a diffusion barrier, in this case preventing the products of the chemical reaction from reacting with the underlying semiconductive or dielectric layer.

Preventing the products of the chemical reaction for depositing tungsten (for instance tungsten fluoride) has revealed to be a very important issue in the fabrication of tungsten interconnect structures. In fact, if diffusion of such products through the barrier layer is not prevented, several problems arise. For instance, in those applications in which a titanium contact layer is formed beneath a titanium nitride barrier layer, tungsten fluoride reacting with titanium may produce conductive protrusions which may, in turn, lead to inter-level and inter-level shorts, thus negatively affecting or compromising the electrical performance of the devices and/or circuits fabricated on the substrate. Moreover, as discussed above, in those applications in which no contact titanium layers are used, tungsten fluoride diffusing through titanium nitride could damage the underlying silicon or silicon-containing layer.

However, conventional methods of forming local interconnect barrier layers have shown to be marginal in their capability to provide adequate barrier properties protecting the underlying layer from the reactive chemistry of the tungsten deposition. In particular, it appears that the low barrier efficiency of the conventional barrier layers arises from organic impurities trapped in the conventional titanium nitride barrier layers during deposition.

Accordingly, several solutions have been proposed in the art to overcome this problem. In an attempt to obtain adhesion/barrier layers that are substantially free from impurities, a post-deposition plasma treatment has been proposed to remove organic impurities trapped in the titanium nitride barrier layers during deposition. During the post-deposition treatment, the titanium nitride barrier layer is introduced into a plasma atmosphere at an elevated temperature. Heating the barrier layer enhances the mobility of the impurities trapped in the layer. Moreover, the ion bombardment during the plasma treatment generates damage at the surface region of the substrate, thereby additionally improving diffusion of the impurities and thus allowing the trapped impurities to be removed from the barrier layer.

However, a further problem arises when a standard post-deposition plasma treatment is carried out for removing organic impurities from the deposited titanium nitride adhesion/barrier layer. It turns out that the plasma treatment allows removing the organic impurities only to a depth of approximately 3.5-7.5 nm. Accordingly, since the titanium nitride adhesion/barrier layers are usually deposited to a thickness of approximately 30-50 nm, a single post-deposition plasma treatment only allows for the removal of the organic impurities from the upper portion of the barrier layers, whereas the lower portion of the barrier layers may still remain contaminated by organic impurities.

In order to obtain barrier layers free from impurities and exhibiting good barrier efficiency, it has been proposed to form the barrier layers by performing a deposition step and a plasma cure step sequentially. That is, the deposition process schematically depicted in FIG. 2a is divided into several deposition steps wherein very thin intermediate titanium nitride layers are sequentially deposited one on the other, and wherein each intermediate titanium nitride layer is individually subjected to a plasma treatment after deposition.

This sequence is schematically depicted in FIGS. 3a-3c, wherein, for reasons of clarity, the formation of a titanium nitride layer 10 on a portion of the bottom of the trench 3 of FIGS. 2a-2c is depicted. For convenience, in FIGS. 3a-3c the titanium contact layer 9 of FIGS. 2a-2c is omitted.

As apparent from FIG. 3a, a first intermediate titanium nitride layer 12a is deposited to a thickness of approximately 3.5-7.5 nm. This thickness essentially corresponds to the depth on which a thermal treatment is effective for removing organic impurities trapped in the intermediate layer 12a during deposition. Once it has been deposited, the intermediate layer 12a is subjected to a plasma treatment and impurities are removed from the whole thickness of the intermediate layer 12a.

During a next step, as depicted in FIG. 3b, a further intermediate titanium nitride layer 12b is deposited on the first intermediate layer 12a and subsequently subjected to a plasma treatment. Since the additional layer 12b is also deposited to a thickness corresponding to the depth on which the plasma treatment is effective for removing impurities, an intermediate layer 12c substantially free of impurities is obtained after the thermal treatment. The sequence is continued by performing intermediate deposition and curing steps until a final layer 12 of a desired thickness is obtained, as depicted in FIG. 3c.

Although barrier layers relatively free of impurities and exhibiting elevated barrier properties can be obtained with the sequential deposition and curing sequence described above, the sequence involves several drawbacks which render it less attractive for applications in the fabrication of integrated circuits. The most important of these drawbacks relates to the fact that the deposition sequence is rather time-consuming. Accordingly, since the formation of interconnect barrier layers is an essential step of the most common technologies for manufacturing integrated circuits, applying the above-described deposition sequence results in the overall manufacturing process being slowed down, thereby increasing the manufacturing costs.

In view of the problems explained above, it is, therefore, desirable to provide a method of forming interconnect barrier layers that may solve or reduce one or more of the problems identified above.

### SUMMARY OF THE INVENTION

Generally, the present invention is based on the consideration that depositing a layer of refractory metal nitride according to the most common deposition techniques results in residual refractory metal being trapped in the layer of refractory metal nitride along with organic impurities. Moreover, the barrier properties of a layer of a refractory metal nitride can be improved by converting the residual refractory metal into refractory metal nitride. It is, therefore, considered that the barrier properties of a layer of a refractory metal nitride are less affected by organic impurities trapped therein if sufficient residual refractory metal is converted, after deposition, into refractory metal nitride. Accordingly, after deposition, a thermal treatment in a nitrogen-containing atmosphere is carried out so as to convert a substantial portion of the residual refractory metal into refractory metal nitride.

According to one embodiment, the present invention relates to a method of forming a layer comprising a refractory metal nitride, the method comprising depositing a layer comprising a refractory metal nitride and subjecting the deposited layer comprising a refractory metal nitride to a thermal treatment in a nitrogen-containing atmosphere so as to convert residual refractory metal in the deposited layer into refractory metal nitride.

According to another embodiment, the present invention relates to a method of forming a local interconnect barrier layer. The method comprises forming a first layer comprising a refractory metal and depositing a second layer comprising a refractory metal nitride on the first layer comprising the refractory metal. The method further comprises subjecting the second layer comprising a refractory metal nitride to a thermal treatment in a nitrogen-containing atmosphere so as to convert residual refractory metal in the second layer into refractory metal nitride.

### BRIEF DESCRIPTION OF THE DRAWINGS

The invention may be understood by reference to the following description taken in conjunction with the accompanying drawings, in which like reference numerals identify like elements, and in which:

FIGS. 1a-1c depict examples of corresponding applications in which a refractory metal is used for forming interconnection structures of integrated circuits;

FIGS. 2a-2c depict a typical prior art sequence flow for forming interconnection structures of a refractory metal;

FIGS. 3a-3c depict typical prior art sequential deposition and plasma curing steps for forming an interconnect barrier layer of a refractory metal nitride; and

FIGS. 4a-4b depict a process for forming an interconnect barrier layer of a refractory metal nitride according to one embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is understood to be particularly advantageous when used for forming interconnect adhesion/barrier layers of titanium nitride. For this reason, examples will be given in the following in which corresponding embodiments of the present invention are applied to the realization of interconnect adhesion/barrier layers of titanium nitride. However, it has to be understood that the present invention is neither limited to the formation of adhesion/barrier layers nor is the present invention limited to applications in which titanium nitride is used, but can be used in any other situation in which the realization of other layers of any refractory metal nitride is required.

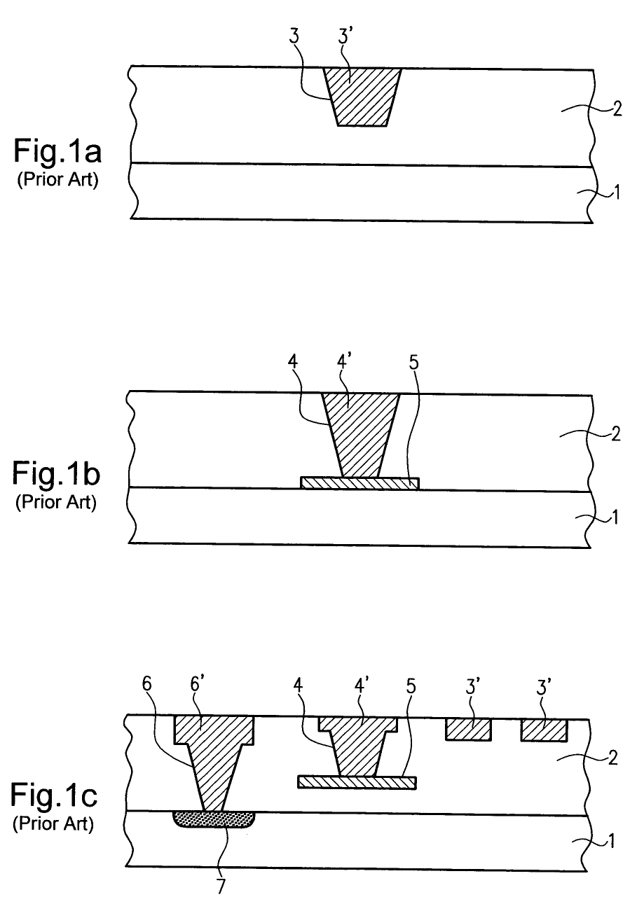

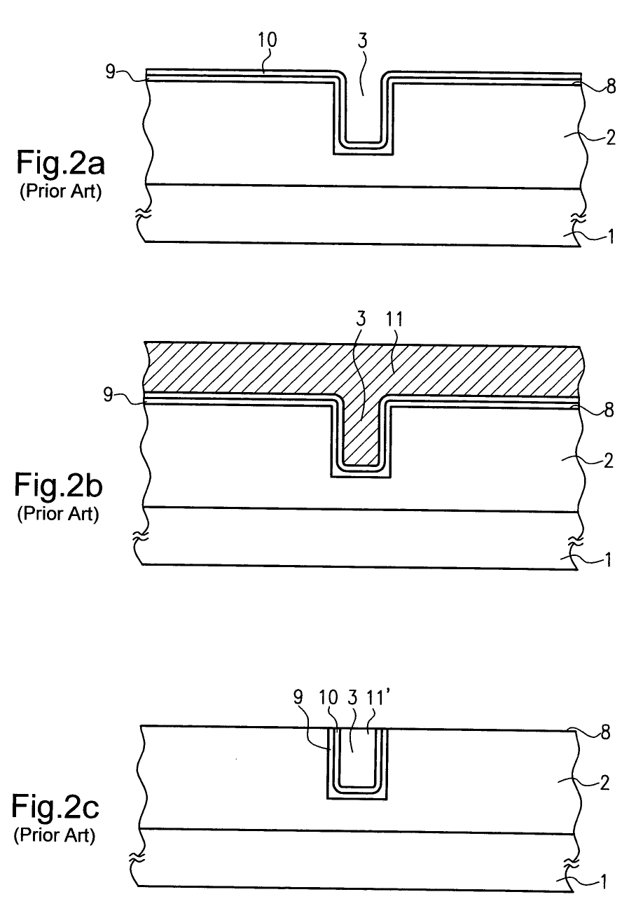

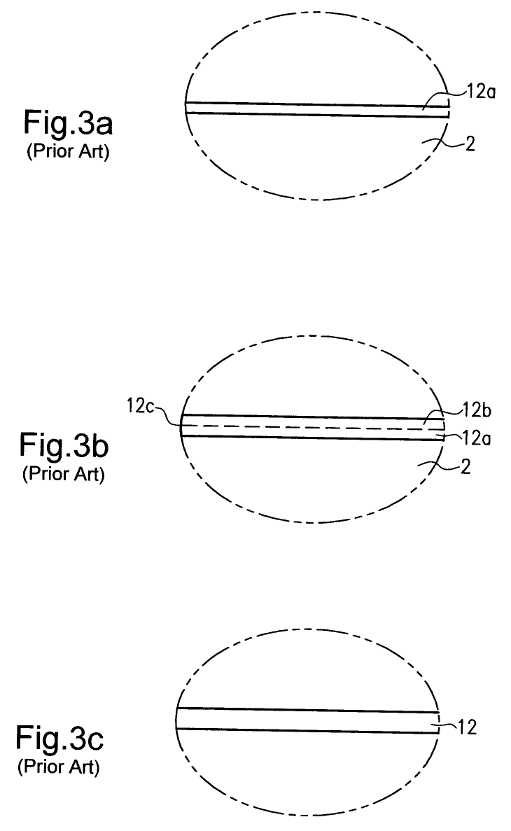

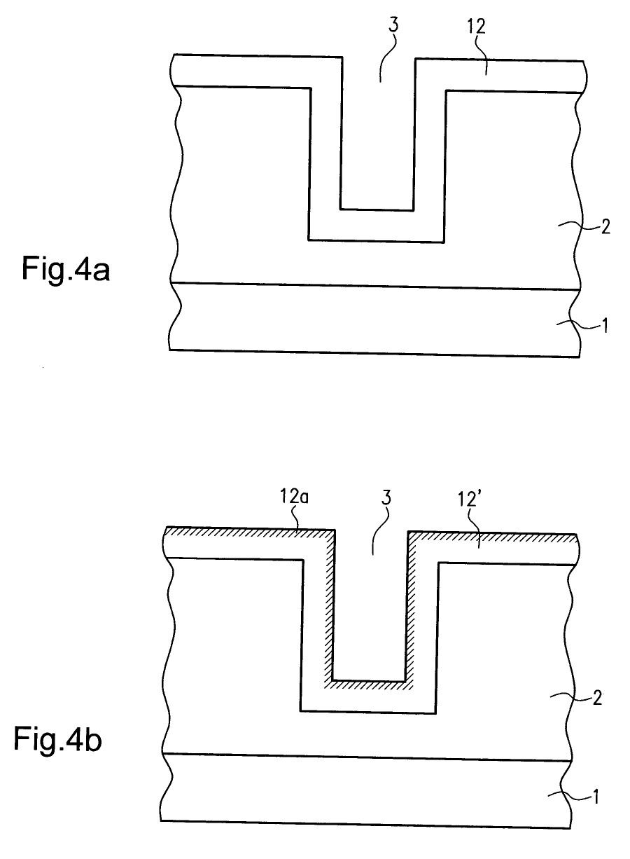

In FIGS. 4a-4b, the features already described with reference to FIGS. 1a-1c, 2a-2c and 3a-3c are identified by the same reference numerals. In FIG. 4a, there is depicted a deposition step for forming interconnect barrier layers according to one illustrative embodiment of the present invention. In FIG. 4a, reference 1 relates to an arbitrary section of a semiconductive substrate, for instance a silicon wafer, on which a dielectric layer 2, for instance a silicon dioxide layer, has been formed. Reference 3 relates to a trench formed in said dielectric layer 2, for instance according to well-known photolithographic and etching techniques. Reference 12 relates to a refractory metal nitride layer, for example, a titanium nitride layer, deposited on the dielectric layer 2.

In FIG. 4b, there is depicted the situation after the layer 12 of FIG. 4a has been subjected to a rapid thermal treatment process. Reference 12′ relates to a refractory metal layer, in particular a titanium nitride layer, after it has been subjected to a rapid thermal anneal process, while other features equivalent to those depicted in FIG. 4a are identified by the same reference numerals.

One illustrative embodiment of the present invention begins with a deposition step as depicted in FIG. 4a. The layer 12 of a refractory metal nitride, for instance titanium nitride, is deposited on the dielectric layer 2. The refractory metal layer 12 is deposited during a single deposition step to a thickness corresponding to the final thickness required for the layer 12. For example, a thickness in the range of 10-50 nm may be provided. For the purpose of depositing the refractory metal nitride layer 12, common deposition techniques may be used, such as, for example, a chemical vapor deposition process. Alternatively, a physical vapor deposition process, as well as a plasma-enhanced deposition process, may be used to this end. It should be appreciated that the present invention is not limited to the specific way the layer 12 is deposited. Preferably, the layer 12 is deposited by CVD, thereby taking advantage of the high degree of conformity that may be accomplished by this deposition technique.

It has been observed, particularly in the case of CVD deposition, that both residual refractory metal and organic impurities are trapped in the layer 12 during deposition. In particular, the impurities are considered to be responsible for the low barrier properties of the deposited layer 12. That is, if tungsten is used for filling the trench 3, without any other step being carried out for improving the barrier properties of the layer 12, the products involved in the chemical reaction for depositing tungsten may diffuse through the layer 12 and react with the underlying layer. For example, in the case depicted in FIG. 4a, the products may react with the underlying dielectric layer 2. In other applications in which an underlying layer of refractory metal, for instance a titanium layer (not depicted in FIGS. 4a-4b), is formed between the dielectric layer 2 and the refractory metal layer 12, these products may react with the underlying layer. Contrary to the conventional approach described above, the present invention proposes an alternative solution for enhancing the barrier properties of the refractory metal layer 12 other than or in combination with removing the organic impurities from said layer 12. In fact, it has been found that the barrier properties may be improved by subjecting the layer 12 to a thermal treatment, such as a rapid thermal treatment, so as to convert residual refractory metal in the layer 12 into refractory metal nitride.

To this end, according to the present invention, a further step is carried out, as depicted in FIG. 4b, during which the layer 12 is subjected to a thermal treatment in a nitrogen-containing atmosphere comprising, for instance, ammonia and/or nitrogen.

In one illustrative embodiment, the heat treatment is performed as a rapid thermal anneal (RTA) process in a nitrogen atmosphere with a temperature in the range of approximately 500-800° C. at sub-atmospheric or atmospheric pressure conditions. The duration of the RTA process is approximately 30-120 seconds for a thickness of approximately 10-50 nm of the layer 12′.

In a further illustrative embodiment, the heat treatment is performed as a rapid thermal anneal (RTA) process in an ammonia atmosphere with a temperature in the range of approximately 500-800° C. at sub-atmospheric or atmospheric pressure conditions. The duration of the RTA process is approximately 30-120 seconds for a thickness of approximately 10-50 nm of the layer 12′.

Subjecting the deposited refractory metal layer 12 to the thermal treatment described above results in a significantly enhanced conversion of residual refractory metal into refractory metal nitride. In one embodiment, as depicted in FIG. 4b, essentially all of the residual refractory metal in proximity of an upper surface 12a of the refractory metal nitride layer 12′, shown as the hatched area in FIG. 4b, is converted into a refractory metal nitride. The depth to which residual refractory metal is converted into refractory metal nitride may be adjusted by the temperature of the thermal treatment and/or the duration in time of the thermal treatment. It has been observed that converting residual refractory metal into refractory metal nitride at least at the upper surface 12a of the layer 12′ improves the barrier properties of the layer 12′. It is believed that the density of the layer 12′ at the upper surface 12a is increased so that diffusion of one or more of the products involved in the deposition of tungsten is more efficiently prevented.

Accordingly, when an interconnect barrier layer is formed, according to the inventive embodiments described above, before depositing tungsten or any other appropriate refractory metal, the layers underlying the refractory metal layer may be efficiently protected, and damage caused by diffusion of products of the deposition chemistry through the barrier layer may be remarkably reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method comprising:
depositing a layer comprising a refractory metal nitride and a residual refractory metal; and
subjecting the deposited layer to a thermal treatment to convert the residual refractory metal in the deposited layer into refractory metal nitride.

2. The method of claim 1, wherein the thermal treatment includes a rapid thermal anneal process.

3. The method of claim 2, wherein the rapid thermal anneal process is performed at a temperature in the range of approximately 500-800° C.

4. The method of claim 2, wherein the rapid thermal anneal process is performed for a time interval in the range of approximately 30-120 seconds.

5. The method of claim 1, wherein said thermal treatment is performed in a nitrogen-containing atmosphere that is established under at least one of sub-atmospheric and atmospheric conditions.

6. The method of claim 1, wherein the layer is deposited by chemical vapor deposition.

7. The method of claim 1, wherein said layer is formed on a semiconductor structure.

8. The method of claim 7, wherein said layer is substantially conformally deposited to cover a bottom and a plurality of sidewalls of at least one of a trench and a via formed in a dielectric layer.

9. The method of claim 8, wherein said layer has a thickness in the range of approximately 10-50 nanometers.

10. The method of claim 5, wherein said nitrogen-containing atmosphere comprises at least one of ammonia and nitrogen gas.

11. The method of claim 8, wherein said dielectric layer comprises silicon dioxide.

12. The method of claim 1, wherein the refractory metal nitride comprises one of titanium nitride and tantalum nitride.

13. A method of forming an interconnect barrier layer, the method comprising:
forming a first layer comprising a refractory metal;
depositing a second layer comprising a refractory metal nitride; and
performing a thermal treatment in a nitrogen-containing atmosphere to convert residual refractory metal of said second layer into refractory metal nitride.

14. The method of claim 13, wherein the thermal treatment includes a rapid thermal anneal process.

15. The method of claim 14, wherein the rapid thermal anneal process is performed at a temperature in the range of approximately 500-800° C.

16. The method of claim 14, wherein the rapid thermal anneal process is performed for a time interval in the range of approximately 30-120 seconds.

17. The method of claim 13, wherein said nitrogen-containing atmosphere is established under at least one of atmospheric and sub-atmospheric conditions.

18. The method of claim 13, wherein the first layer comprising the refractory metal is deposited by chemical vapor deposition.

19. The method of claim 13, wherein the second layer comprising the refractory metal nitride is deposited by chemical vapor deposition.

20. The method of claim 13, wherein said refractory metal nitride layer is formed on a semiconductor structure.

21. The method of claim 20, wherein said layer comprised of said refractory metal is substantially conformally deposited to cover a bottom and a plurality of sidewalls of at least one of a trench and a via formed in a dielectric layer.

22. The method of claim 13, wherein said layer of refractory metal has a thickness in the range of approximately 10-50 nanometers.

23. The method of claim 13, wherein a thickness of the first layer is in the range of approximately 20-70 nanometers.

24. The method of claim 13, wherein said nitrogen-containing atmosphere comprises at least one of ammonia and nitrogen gas.

25. The method of claim 21, wherein said dielectric layer comprises silicon dioxide.

26. The method of claim 13, wherein the refractory metal nitride comprises at least one of titanium nitride and tantalum nitride.

27. The method of claim 13, wherein said refractory metal comprises at least one of titanium and tantalum.

28. The method of claim 1, wherein said thermal treatment is performed in an ammonia-containing atmosphere.

29. The method of claim 28, wherein said ammonia-containing atmosphere is established under at least one of sub-atmospheric and atmospheric conditions.

30. A method, comprising:
forming an opening in a layer of insulating material;
depositing a layer comprising a refractory metal nitride and a residual refractory metal in at least said opening; and
subjecting the deposited layer to a thermal treatment.

31. The method of claim 30, wherein the thermal treatment includes a rapid thermal anneal process.

32. The method of claim 30, wherein said thermal treatment is performed in a nitrogen-containing atmosphere.

33. The method of claim 30, wherein said thermal treatment is performed in an ammonia-containing atmosphere.

34. The method of claim 30, wherein said thermal treatment is performed at a temperature in the range of approximately 500-800° C.

35. The method of claim 30, wherein said thermal treatment is performed for a time interval in the range of approximately 30-120 seconds.

36. The method of claim 30, wherein the layer is deposited by chemical vapor deposition.

37. The method of claim 30, wherein said layer is formed on a semiconductor structure.

38. The method of claim 30, wherein said layer is substantially conformally deposited to cover a bottom and a plurality of sidewalls of said opening.

39. The method of claim 30, wherein said layer has a thickness in the range of approximately 10-50 nanometers.

40. The method of claim 30, wherein said layer of insulating material comprises silicon dioxide.

41. The method of claim 30, wherein said layer comprises one of titanium nitride and tantalum nitride.

42. The method of claim 30, wherein subjecting the layer to a thermal treatment comprises subjecting the layer to a thermal treatment to convert the residual refractory metal to a refractory metal nitride.
